(19) United States
(12) Patent Application Publication
(10) Pub. No.: US 2011/0132582 A1
(43) Pub. Date: Jun. 9, 2011

(54) FAN MODULE AND HEAT DISSIPATION DEVICE INCORPORATING THE SAME

(75) Inventor: HAO-DER CHENG, Tu-Cheng (TW)

(73) Assignee: HON HAI PRECISION INDUSTRY CO., LTD., Tu-Cheng (TW)

(21) Appl. No.: 12/641,214

(22) Filed: Dec. 17, 2009

(30) Foreign Application Priority Data
Dec. 7, 2009 (TW) 98141661

(51) Int. Cl. H05K 7/20; F04D 25/06; F04D 25/08; H01L 23/467

(52) U.S. Cl. 165/121; 361/697; 417/423.14; 165/185

(57) ABSTRACT

An exemplary fan module a main fan and an assist fan. The main fan includes a rotor. The rotor of the main fan includes a hub and a plurality of blades around the hub. The assist fan is located below the hub of the main fan. The assist fan includes a rotor. The rotor of the assist fan includes a shaft and a plurality of blades around the shaft. The shaft of the assist fan is fixed on the hub of the main fan. The rotor of the assist fan is driven to rotate by the main fan, and therefore produces airflow towards a central portion of a heat sink.

### CROSS-REFERENCE TO RELATED APPLICATION

This application is related to a co-pending application entitled “HEAT DISSIPATION DEVICE AND FAN MODULE THEREOF” (attorney docket number US 30615), assigned to the same assignee of this application and filed on the same date.

### BACKGROUND

1. Technical Field

The disclosure generally relates to heat dissipation, and particularly to a heat dissipation device having an improved fan module.

2. Description of Related Art

A typical heat dissipation device includes a heat sink and a cooling fan arranged on the heat sink. Electronic components are usually attached to a central portion of the heat sink, the location at which heat generated by the electronic component is primarily concentrated. The cooling fan includes an impeller. The impeller includes a hub and a plurality of blades around the hub. During operation of the cooling fan, the impeller rotates and produces airflow towards the heat sink. However, due to blocked access to the hub of the impeller, only a small portion of the airflow reaches the central portion of the heat sink immediately under the hub, such that heat concentrated at the central portion of the heat sink cannot be efficiently dissipated.

What is needed, therefore, is a heat dissipation device and a fan module of the heat dissipation device which can overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross sectional, schematic view of a heat dissipation device in accordance with one embodiment of the disclosure.

FIG. 2 is an enlarged view of a fan module of the heat dissipation device of FIG. 1.

### DETAILED DESCRIPTION

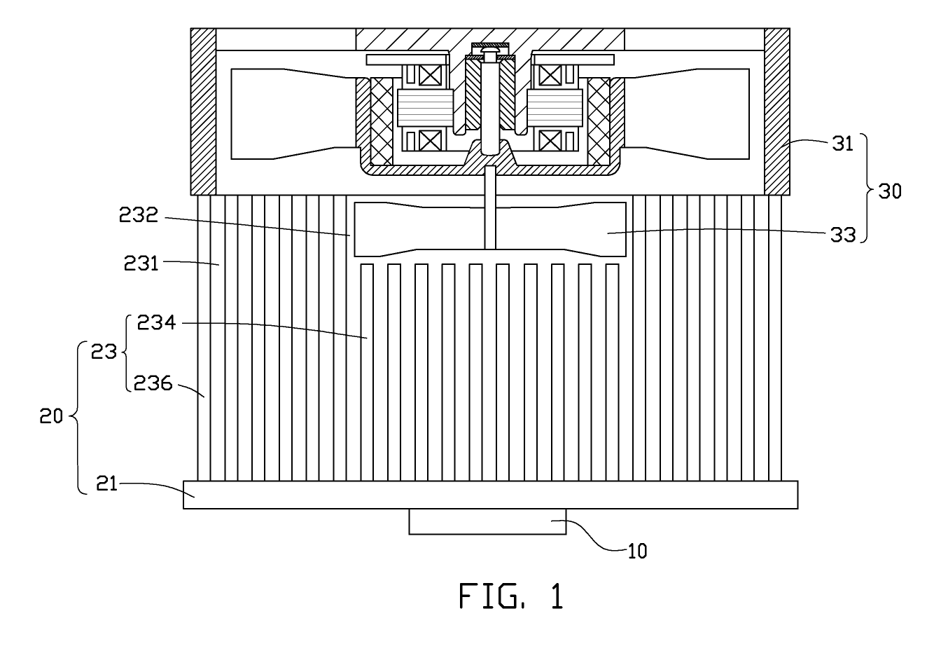

Referring to FIG. 1, a heat dissipation device in accordance with one embodiment is shown. The heat dissipation device is mounted on an electronic component 10, such as a central processing unit (CPU), for dissipating heat therefrom. The heat dissipation device includes a heat sink 20 and a fan module 30 arranged on the heat sink 20.

The heat sink 20 includes a substrate 21 and a plurality of fins 23 extending perpendicularly up from the substrate 21. The substrate 21 is attached to the electronic component 10 at a central portion of a bottom surface thereof. The fins 23 are parallel to and spaced from each other. An air channel 231 is defined between every two adjacent fins 23. The fins 23 includes a plurality of inner fins 234 at a central portion of the heat sink 10, and a plurality of outer fins 236 around the inner fins 234. The inner fins 234 each have a length less than that of the outer fins 236, and therefore a recess 232 is defined in the central portion of the heat sink 20 over the inner fins 234.

The fan module 30 includes a main fan 31 and an assist fan 33 located below the main fan 31. The main and assist fans 31, 33 are axial fans.

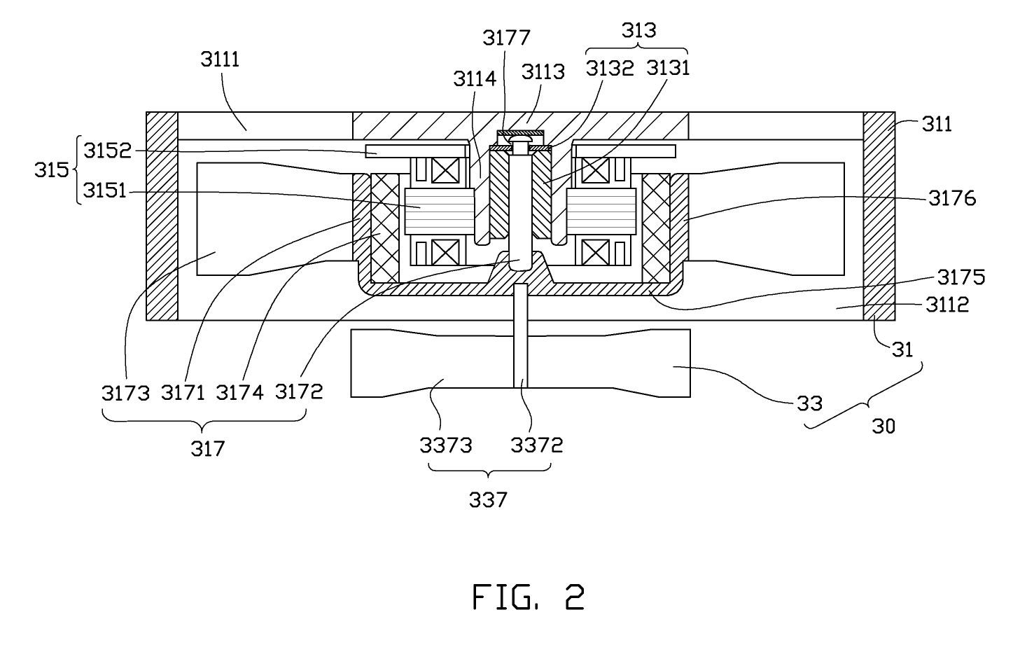

Referring to FIG. 2, the main fan 31 includes a frame 311, a bearing system 313, a stator 315 mounted on the frame 311, and a rotor 317 covering the stator 315.

The frame 311 is mounted on the outer fins 236 of the heat sink 20. The frame 311 is substantially rectangular and hollow. The frame 311 defines an air inlet 3111 at a top end thereof, and an air outlet 3112 at a bottom end thereof. A base 3113 is formed at a central portion of the top end of the frame 311. The base 3113 is connected to the frame 311 via a plurality of ribs (not labeled). The air outlet 3112 is defined between the ribs. A central tube 3114 extends perpendicularly down from a central portion of the base 3113.

The bearing system 313 is received in the central tube 3114 of the frame 311. The bearing system 313 includes a sleeve 3131 and a locking ring 3132 located above the sleeve 3131. The sleeve 3131 is hollow and cylindrical, and the locking ring 3132 is annular.

The stator 315 includes a circuit board 3151 and a coil assembly 3152 located on the circuit board 3151. The circuit board 3151 and the coil assembly 3152 are mounted around the central tube 3114 of the frame 311.

The rotor 317 is rotatably mounted around the coil assembly 3152 of the stator 315. The rotor 317 includes a hub 3171, a shaft 3172, a plurality of blades 3173, and a magnet 3174. The hub 3171 is semi-enclosed, and includes a bottom wall 3175 and a sidewall 3176 extending perpendicularly up from an outer periphery of the bottom wall 3175. A bottom end of the shaft 3172 is fixed at a central portion of the bottom wall 3175 of the hub 3171. A middle portion of the shaft 3172 is received in the sleeve 3131. A top end of the shaft 3172 defines an annular notch 3177 engaged with the locking ring 3132, so as to prevent the rotor 317 from falling off. The rotor 317 with the shaft 3172 is rotatable with respect to the bearing system 313. The blades 3173 extend radially out from an outer circumferential surface of the sidewall 3176 of the hub 3171. The magnet 3174 is annular, and contacted with an inner circumferential surface of the sidewall 3176 of the hub 3171.

The assist fan 33 is located under the hub 3171 of the main fan 31, and received in the recess 232 of the heat sink 20. The assist fan 33 includes a rotor 337.

The rotor 337 is located under the hub 3171 of the main fan 31. The rotor 337 has an outer diameter equal to that of the hub 3171 of the rotor 317 of the main fan 31. The rotor 337 includes a shaft 3372 and a plurality of blades 3373 around a bottom end of the shaft 3372. A top end of the shaft 3372 is fixed at the central portion of the bottom wall 3175. The blades 3373 extend radially out from an outer circumferential surface of the shaft 3372. Outer sides of the blades 3373 of the assist fan 33 away from the shaft 3372 are just located within the hub 3171 of the main fan 31 along a radial direction of the rotor 317 of the main fan 31.

During operation, the rotor 317 of the main fan 31 of the fan module 30 rotates and drives the assist fan 33 fixed on the rotor 317 of the main fan 31 to rotate. Airflow produced by the blades 3173 flows towards the outer fins 236 of the heat sink 20 via the air outlet 3112 of the main fan 31, and then enters corresponding air passages 231 between the outer fins 236 of heat sink 20, thereby taking heat away. Airflow produced by the blades 3373 of the rotor 337 of the assist fan 33 flows directly towards the inner fins 234 of heat sink 20, and then enters corresponding air passages 231 between the inner fins 234 of heat sink 20, thereby taking away the heat concentrated at the central portion of the heat sink 20.

In the present heat dissipation device, the rotor 337 of the assist fan 33 is fixed on the hub 3171 of the rotor 317 of the assist fan 31. The rotor 337 of the assist fan 33 is driven to rotate by the main fan 31, and produces airflow towards the central portion of the heat sink 20. Thus, heat concentrated at the central portion of the heat sink 20 can be efficiently dissipated by the assist fan 33. This prevents the electronic component 10 at the central portion of the substrate 21 of the heat sink 20 overheating. In addition, the assist fan 33 is driven to rotate by the main fan 31. Therefore, only the rotor 337 is required in the assist fan 33. A blocked access to the shaft 3372 of the rotor 337 of the assist fan 33 is almost non-existent. Thus, an airflow dead area under the hub 3171 of the main fan 31 is reduced, and the heat dissipation efficiency of the heat dissipation device is improved.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A fan module, comprising:
a main fan comprising a rotor, the rotor of the main fan comprising a hub and a plurality of blades around the hub; and
an assist fan located below the hub of the main fan, the assist fan comprising a rotor, the rotor of the assist fan comprising a shaft and a plurality of blades around the shaft, the shaft of the assist fan fixed on the hub of the main fan.

2. The fan module of claim 1, wherein the hub of the main fan includes a bottom wall and a sidewall extending perpendicularly up from an outer periphery of the bottom wall, a top end of the shaft of the assist fan fixed at a central portion of the bottom wall of the hub of the main fan, the blades of the assist fan disposed around a bottom end of the shaft of the assist fan.

3. The fan module of claim 1, wherein the rotor of the assist fan has an outer diameter equal to that of the hub of the rotor of the main fan.

4. The fan module of claim 1, wherein outer sides of the blades of the assist fan away from the shaft of the assist fan are just located within the hub of the main fan along a radial direction of the rotor of the main fan.

5. A fan module, comprising:
an main rotor comprising a hub, a main shaft and a plurality of main blades, the hub comprising a circular wall and an annular sidewall surrounding the circular wall, the shaft of the main rotor fixed on the circular wall, the blades extending from the sidewall of the hub; and
an assist rotor comprising an assist shaft fixed on the hub and a plurality of assist blades fixed around the shaft, the main shaft and the assist shaft located at opposite sides of the circular wall of the hub of the main rotor.

6. The fan module of claim 5, wherein the assist rotor has an outer diameter equal to that of the hub of the main rotor.

7. The fan module of claim 5, wherein outer sides of the assist blades of the assist rotor away from the assist shaft are just located within the hub of the main rotor along a radial direction of the main rotor.

8. A heat dissipation device, comprising:
a heat sink; and
a fan module arranged on the heat sink, the fan module comprising:
a main fan comprising a rotor, the rotor of the main fan comprising a hub and a plurality of blades around the hub; and
an assist fan located below the hub of the main fan, the assist fan comprising a rotor, the rotor of the assist fan comprising a shaft and a plurality of blades around the shaft, the shaft of the assist fan fixed on the hub of the main fan.

9. The heat dissipation device of claim 8, wherein the heat sink defines a recess in a central portion thereof, the assist fan of the fan module received in the recess.

10. The heat dissipation device of claim 8, wherein the hub of the main fan includes a bottom wall and a sidewall extending perpendicularly up from an outer periphery of the bottom wall, a top end of the shaft of the assist fan fixing at a central portion of the bottom wall of the hub of the main fan, the blades of the assist fan disposed around a bottom end of the shaft of the assist fan.

11. The heat dissipation device of claim 8, wherein the rotor of the assist fan has an outer diameter equal to that of the hub of the rotor of the main fan.

12. The heat dissipation device of claim 8, wherein outer sides of the blades of the assist fan away from the shaft of the assist fan are just located within the hub of the main fan along a radial direction of the rotor of the main fan.
